(19) United States
(12) Patent Application Publication
(10) Pub. No.: US 2025/0194070 A1
(43) Pub. Date: Jun. 12, 2025

(54) INTEGRATED CIRCUIT STRUCTURES WITH TRANSISTOR GATE-CHANNEL ARRANGEMENTS FOR STATIC RANDOM-ACCESS MEMORY

(71) Applicants: Tao Chu, Portland, OR (US); Minwoo Jang, Portland, OR (US); Paul Packan, Hillsboro, OR (US); Yanbin Luo, Portland, OR (US); Yue Zhong, Portland, OR (US); Chiao-Ti Huang, Portland, OR (US); Robin Chao, Portland, OR (US); Feng Zhang, Hillsboro, OR (US); Ting-Hsiang Hung, Beaverton, OR (US); Chia-Ching Lin, Portland, OR (US); Yang Zhang, Rio Rancho, NM (US); Kan Zhang, HILLSBORO, OR (US); Chung-Hsun Lin, Portland, OR (US); Anand S. Murthy, Portland, OR (US); Guowei Xu, Portland, OR (US)

(72) Inventors: Tao Chu, Portland, OR (US); Minwoo Jang, Portland, OR (US); Paul Packan, Hillsboro, OR (US); Yanbin Luo, Portland, OR (US); Yue Zhong, Portland, OR (US); Chiao-Ti Huang, Portland, OR (US); Robin Chao, Portland, OR (US); Feng Zhang, Hillsboro, OR (US); Ting-Hsiang Hung, Beaverton, OR (US); Chia-Ching Lin, Portland, OR (US); Yang Zhang, Rio Rancho, NM (US); Kan Zhang, HILLSBORO, OR (US); Chung-Hsun Lin, Portland, OR (US); Anand S. Murthy, Portland, OR (US); Guowei Xu, Portland, OR (US)

(21) Appl. No.: 18/530,501

(22) Filed: Dec. 6, 2023

(51) Int. Cl. H10B 10/00; H01L 29/06; H01L 29/423; H01L 29/775; H01L 29/786

(52) U.S. Cl. CPC H10B 10/125; H10D 30/43; H10D 30/6735; H10D 30/6757; H10D 62/121

(57) ABSTRACT

Disclosed herein are IC structures with transistor gate-channel arrangements for SRAM, and related methods and devices. Example IC structure may include a memory cell with a plurality of transistors including transistors of a first type and transistors of a second type (e.g., the first type may be an N-type and the second type may be a P-type, or vice versa), an individual transistor comprising a transistor gate-channel arrangement that includes a channel material and a transistor gate stack, and the transistor gate stack comprising a gate electrode material and a high-k dielectric between the gate electrode material and the channel material. The transistor gate-channel arrangement of at least one transistor of the first type further includes a dipole material or a halogen (e.g., fluorine), which are absent in the transistor gate-channel arrangements of all of the transistors of the second type.

### BACKGROUND

Embedded memory is important to the performance of modern system-on-a-chip (SoC) technology. Static random-access memory (SRAM) is one example that may be implemented as embedded memory, particularly suitable for modern SoC due to its compatibility with fabrication processes used to manufacture computing logic, e.g., front end of line (FEOL) processes. In some deployment scenarios, SRAM may have advantages over other types of memory, such as dynamic random-access memory (DRAM).

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional side view of a transistor gate-channel arrangement including a transistor gate stack, in accordance with various embodiments.

FIGS. 2-5 are cross-sectional side views of example single-gate transistors including a transistor gate stack, in accordance with various embodiments.

FIGS. 6-7 are cross-sectional side views of example double-gate transistors including a transistor gate stack, in accordance with various embodiments.

FIGS. 8A and 8B are perspective and cross-sectional side views, respectively, of an example tri-gate transistor including a transistor gate stack, in accordance with various embodiments.

FIGS. 9A and 9B are perspective and cross-sectional side views, respectively, of an example all-around gate transistor including a transistor gate stack, in accordance with various embodiments.

FIG. 10 provides an electric circuit diagram of an example SRAM cell, according to some embodiments of the present disclosure.

FIG. 11 is a cross-sectional side view of a transistor gate-channel arrangement including a transistor gate stack with a dipole layer, in accordance with various embodiments.

FIG. 12 is a cross-sectional side view of a transistor gate-channel arrangement including a transistor gate stack with implanted halogens, in accordance with various embodiments.

FIG. 13 is a top view of a wafer and dies that may include any of the IC structures disclosed herein, in accordance with any of the embodiments disclosed herein.

FIG. 14 is a side, cross-sectional view of an IC device that may include any of the IC structures disclosed herein, in accordance with any of the embodiments disclosed herein.

FIG. 15 is a side, cross-sectional view of an IC package that may include any of the IC structures disclosed herein, in accordance with various embodiments.

FIG. 16 is a side, cross-sectional view of an IC device assembly that may include any of the IC structures disclosed herein, in accordance with any of the embodiments disclosed herein.

FIG. 17 is a block diagram of an example electrical device that may include any of the IC structures disclosed herein, in accordance with any of the embodiments disclosed herein.

### DETAILED DESCRIPTION

Disclosed herein are IC structures with transistor gate-channel arrangements for SRAM, and related methods and devices. Example IC structure may include a memory cell with a plurality of transistors including transistors of a first type and transistors of a second type (e.g., the first type may be an N-type and the second type may be a P-type, or vice versa), an individual transistor comprising a transistor gate-channel arrangement that includes a channel material and a transistor gate stack, and the transistor gate stack comprising a gate electrode material and a high-k dielectric between the gate electrode material and the channel material. The transistor gate-channel arrangement of at least one transistor of the first type further includes a dipole material or a halogen (e.g., fluorine), which are absent in the transistor gate-channel arrangements of all of the transistors of the second type.

The performance of SRAM may depend on the number of factors. One factor is the minimum operating voltage (Vmin) at which the SRAM can reliably function. The minimum operating voltage is a critical parameter in semiconductor devices, as it represents the lower limit below which the device may experience errors or fail to operate correctly. Achieving a lower minimum operating voltage is often desirable in semiconductor design because it allows for lower power consumption and better energy efficiency. However, designing SRAM to operate at lower voltages presents challenges. One challenge is related to a phenomenon of a threshold voltage (Vt) anti-correlation. In semiconductor device physics and technology, the threshold voltage of a transistor is a critical parameter that determines when a transistor switches from the off-state to the on-state. In a complementary metal-oxide-semiconductor (CMOS) technology, which utilizes both N-type and P-type transistors, there is often an inherent relationship between the threshold voltages of the two types of transistors. Specifically, there tends to be an anti-correlation between the threshold voltages of N-type and P-type transistors in that, if the threshold voltage of N-type transistors is adjusted to be higher (or lower) for a specific design or technology node, the threshold voltage of the P-type transistors will tend to be adjusted in the opposite direction to maintain the desired performance characteristics and ensure proper circuit functionality. An individual memory cell of SRAM utilizes both N-type and P-type transistors and, thus, typically exhibits threshold voltage anti-correlation. In turn, threshold voltage anti-correlation degrades the minimum operating voltage of SRAM.

SRAM cells disclosed herein include a dipole material or a halogen (e.g., fluorine) in gate-channel arrangements of some or all transistors of one type but exclude such materials in gate-channel arrangements of all of the transistors of the other type. Introduction of dipole or other dopant material such as halogen in gate stacks of SRAM transistors of one type but not the other type may change the correlation between the threshold voltages of N-type and P-type transistors, reducing or eliminating threshold voltage anti-correlation, which may allow improving the minimum operating voltage of SRAM. The gate-channel arrangements disclosed herein may enable the use of a wider array of gate electrode materials in gate stacks, while achieving desirable gate control and minimum operating voltage of SRAM, than realizable using conventional approaches.

IC structures with transistor gate-channel arrangements for SRAM as described herein, in particular IC structures with SRAM having transistor gate-channel arrangements with dipole materials or halogens in one or more transistors of one type but in none of the transistors of the other type, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

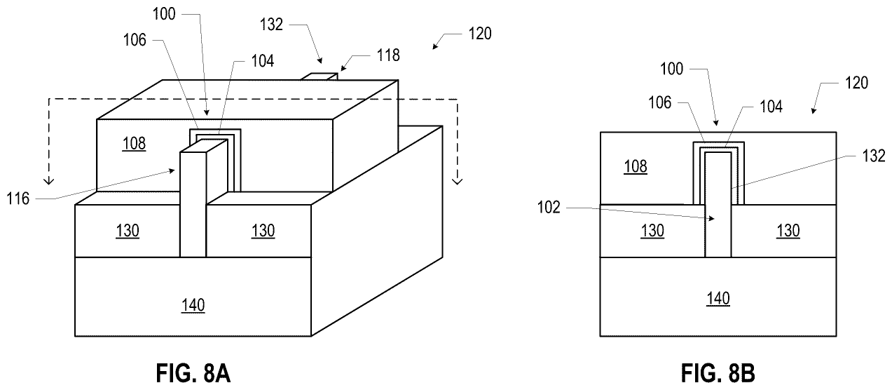

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 8A-8B, such a collection may be referred to herein without the letters, e.g., as “FIG. 8.”

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures with transistor gate-channel arrangements for SRAM as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

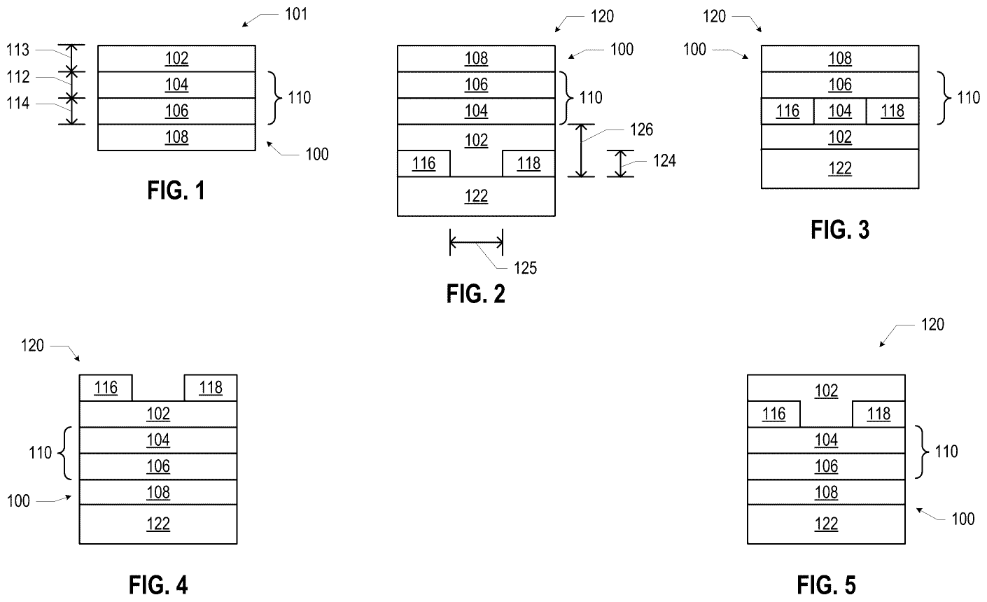

FIG. 1 is a cross-sectional side view of a transistor gate-channel arrangement 101 including a channel material 102 and a transistor gate stack 100 (also referred to as a “gate stack 100” herein), in accordance with various embodiments. FIGS. 2-9 illustrate transistors of different architectures in which the gate stack 100 of FIG. 1 may be implemented. N-type and P-type transistors of IC structures with transistor gate-channel arrangements for SRAM as described herein, in particular IC structures with SRAM having transistor gate-channel arrangements with dipole materials or halogens in one or more transistors of one type but in none of the transistors of the other type, may be transistors of any of the architectures described with reference to FIGS. 2-9.

Turning to the details of FIG. 1, as shown, the transistor gate stack 100 may include a gate electrode material 108, and a gate dielectric stack 110 disposed between the gate electrode material 108 and the channel material 102.

The channel material 102 may be composed of semiconductor material systems including, for example, N-type or P-type materials systems. In some embodiments, the channel material 102 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 102 may include a combination of semiconductor materials. In some embodiments, the channel material 102 may include a monocrystalline semiconductor, such as silicon (Si) or germanium (Ge). In some embodiments, the channel material 102 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (e.g., for the embodiments where a transistor 120 of any of FIGS. 2-9 is an N-type metal oxide semiconductor (NMOS) transistor), the channel material 102 may include a III-V material having a relatively high electron mobility, such as, but not limited to InGaAs, InP, InSb, and InAs. For some such embodiments, the channel material 102 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (e.g., for the embodiments where a transistor 120 of any of FIGS. 2-9 is a P-type metal oxide semiconductor (PMOS) transistor), the channel material 102 may advantageously be a group IV material having a high hole mobility, such as, but not limited to Ge or a Ge-rich SiGe alloy. For some example embodiments, the channel material 102 may have a Ge content between 0.6 and 0.9, and advantageously may be at least 0.7.

In some embodiments, the channel material 102 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if a transistor is a thin-film transistor (TFT), the channel material 102 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. The channel material 102 may have a thickness 113. In some embodiments, the thickness 113 may be between about 5 and 75 nanometers, including all values and ranges therein, e.g., between about 5 and 30 nanometers.

The gate electrode material 108 may include at least one P-type work function metal or N-type work function metal, depending on whether the transistor gate stack 100 is to be included in a P-type transistor or an N-type transistor. For a P-type transistor, metals that may be used for the gate electrode material 108 may include, but are not limited to, ruthenium, palladium, platinum, cobalt, nickel, and conductive metal oxides (e.g., ruthenium oxide). For an N-type transistor, metals that may be used for the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of two or more metal layers, where one or more metal layers are work function metal layers and at least one metal layer is a fill metal layer. Further metal layers may be included for other purposes, such as to act as a barrier layer.

The gate dielectric stack 110 may include a high-k dielectric 106 and an insulator material 104, arranged in the gate stack 100 so that the insulator material 104 is disposed between the high-k dielectric 106 and the channel material 102. The insulator material 104 may be in contact with the channel material 102, and may provide the interface between the channel material 102 and the remainder of the gate dielectric stack 110. In various embodiments, the insulator material 104 may have a dielectric constant lower than that of the high-k dielectric 106. In some embodiments, the insulator material 104 may include silicon and oxygen. In other embodiments, the insulator material 104 may include IGZO. In some embodiments, the insulator material 104 may be an amorphous, crystalline, or semi crystalline oxide semiconductor. In some embodiments, the insulator material 104 may be in contact with the high-k dielectric 106, while in other embodiments, an intermediate material may be disposed between the insulator material 104 and the high-k dielectric 106. The insulator material 104 may have a thickness 112. In some embodiments, the thickness 112 may be between 0.5 nanometers and 5 nanometers (e.g., between 5 angstroms and 3 nanometers, or between 6 angstroms and 3 nanometers).

The high-k dielectric 106 may include elements such as hafnium, silicon, oxygen, titanium, tantalum, lanthanum, aluminum, zirconium, barium, strontium, yttrium, lead, scandium, niobium, and zinc. Examples of high-k materials that may be used in the high-k dielectric 106 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the high-k dielectric 106 during manufacture of the gate stack 100 to improve the quality of the high-k dielectric 106. The high-k dielectric 106 may have a thickness 114. In some embodiments, the thickness 114 may be between 0.5 nanometers and 3 nanometers (e.g., between 1 and 3 nanometers, or between 1 and 2 nanometers).

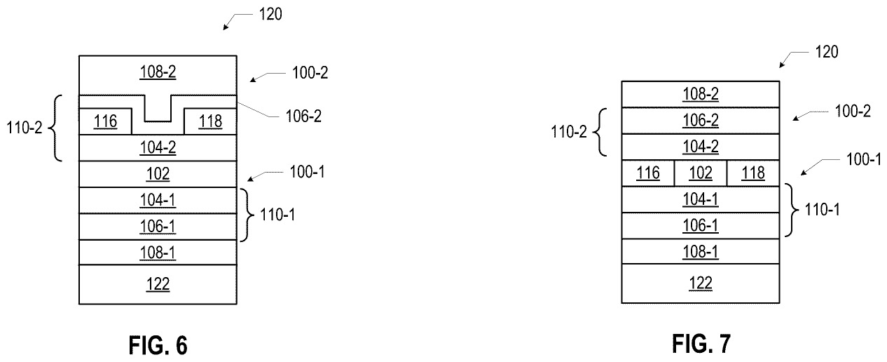

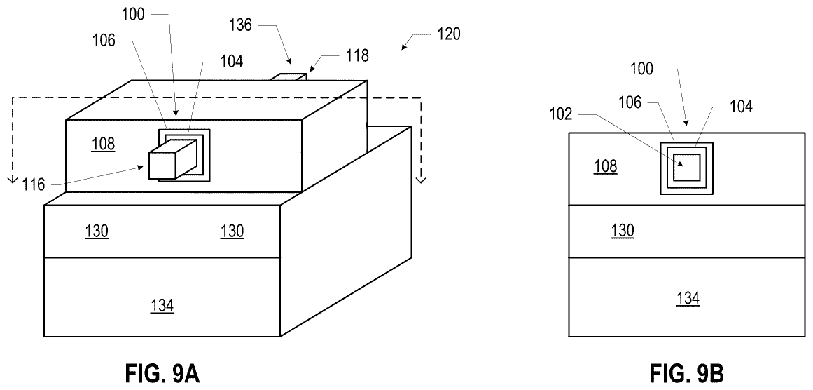

The transistor gate stack 100 may be included in any suitable transistor structure. For example, FIGS. 2-5 are cross-sectional side views of example single-gate transistors 120 including a transistor gate stack 100, FIGS. 6-7 are cross-sectional side views of example double-gate transistors 120 including a transistor gate stack 100, FIGS. 8A and 8B are perspective and cross-sectional side views, respectively, of an example tri-gate transistor 120 including a transistor gate stack, and FIGS. 9A and 9B are perspective and cross-sectional side views, respectively, of an example all-around gate transistor 120 including a transistor gate stack, in accordance with various embodiments. The transistors 120 illustrated in FIGS. 2-9 do not represent an exhaustive set of transistor structures in which a gate stack 100 may be included, but that may provide examples of such structures. Although particular arrangements of materials are discussed below with reference to FIGS. 2-9, intermediate materials may be included in the gate stacks 100 of the transistors 120 as discussed above with reference to FIG. 1. Note that FIGS. 2-9 are intended to show relative arrangements of the components therein, and that transistors 120 may include other components that are not illustrated (e.g., electrical contacts to the source region 116 and the drain region 118 to transport current in and out of the transistors 120). Any of the components of the transistors 120 discussed below with reference to FIGS. 2-9 may take the form of any of the embodiments of those components discussed above with reference to FIG. 1. Additionally, although various components of the transistors 120 are illustrated in FIGS. 2-9 as being planar rectangles or formed of rectangular solids, this is simply for ease of illustration, and embodiments of these transistors 120 may be curved, rounded, or otherwise irregularly shaped as dictated by the manufacturing processes used to fabricate the transistors 120.

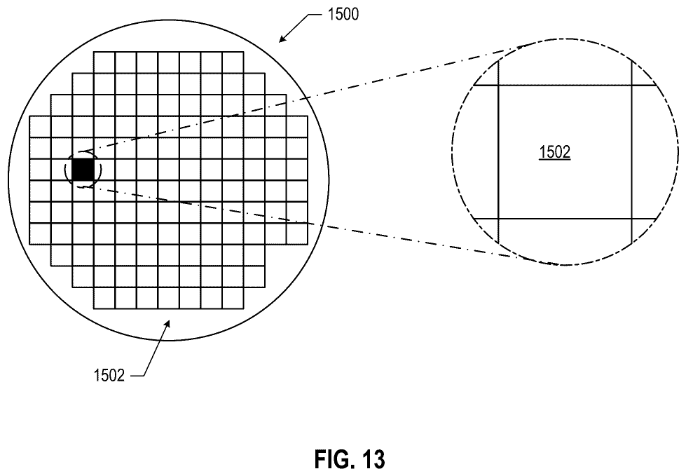

FIG. 2 depicts a transistor 120 including a transistor gate stack 100 and having a single “top” gate provided by the gate electrode material 108 and the gate dielectric stack 110 (which includes the high-k dielectric 106 and the insulator material 104). The gate dielectric stack 110 may be disposed between the gate electrode material 108 and the channel material 102. The gate dielectric stack 110 may border the channel material 102; in particular, the insulator material 104 may contact the channel material 102 without any intervening material in some embodiments. In the embodiment of FIG. 2, the gate stack 100 is shown as disposed on a support 122. The support 122 may be any structure, e.g., a substrate, a die, a wafer, or a chip, on which the gate stack 100, or other elements of the transistor 120, is disposed. The support 122 may, e.g., be the wafer 1500 of FIG. 13, discussed below, and may be, or be included in, a die, e.g., the singulated die 1502 of FIG. 13, discussed below. In some embodiments, the support 122 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 122 may be a printed circuit board (PCB) substrate, a package substrate, an interposer, a wafer, or a die. In some embodiments, the support 122 may include an insulating layer, such as an oxide isolation layer. For example, in the embodiments of FIGS. 2 and 3, the support 122 may include a semiconductor material and an interface layer dielectric (ILD) disposed between the semiconductor material and the source region 116, the channel material 102, and the drain region 118, to electrically isolate the semiconductor material of the support 122 from the source region 116, the channel material 102, and the drain region 118 (and thereby mitigate the likelihood that a conductive pathway will form between the source region 116 and the drain region 118 through the support 122). Examples of ILDs that may be included in a support 122 in some embodiments may include silicon oxide, silicon nitride, aluminum oxide, and/or silicon oxynitride. Any suitable ones of the embodiments of the support 122 described with reference to FIG. 2 may be used for the substrates 122 of others of the transistors 102 disclosed herein.

As noted above, the transistor 120 may include a source region 116 and a drain region 118 disposed on the support 122, with the channel material 102 disposed between the source region 116 and the drain region 118 so that at least some of the channel material 102 is coplanar with at least some of the source region 116 and the drain region 118. The source region 116 and the drain region 118 may have a thickness 124, and the channel material 102 may have a thickness 126. The thickness 126 may take the form of any of the embodiments of the thickness 113 discussed above with reference to FIG. 1. In some embodiments, the thickness 124 may be less than the thickness 126 (as illustrated in FIG. 2, with the source region 116 and the drain region 118 each disposed between some of the channel material 102 and the support 122), while in other embodiments, the thickness 124 may be equal to the thickness 126. In some embodiments, the channel material 102, the insulator material 104, the high-k dielectric 106, and/or the gate electrode material 108 may conform around the source region 116 and/or the drain region 118. The source region 116 and the drain region 118 may be spaced apart by a distance 125 that is the gate length of the transistor 120. In some embodiments, the gate length may be between about 5 and 40 nanometers, including all values and ranges therein (e.g., between about 22 and 35 nanometers, or between about 20 and 30 nanometers).

The source region 116 and the drain region 118 may be highly doped semiconductors, e.g., with dopant concentrations of about 10²¹ dopants per cubic centimeter (cm⁻³), in order to advantageously form Ohmic contacts with the respective source or drain contacts (not shown in FIG. 1), although these regions may also have lower dopant concentrations and may form Schottky contacts in some implementations. Irrespective of the exact doping levels, the source region 116 and the drain region 118 of a transistor are the regions having dopant concentration higher than in other regions, e.g., higher than a dopant concentration in the transistor channel (i.e., in a channel material extending between the source region 116 and the drain region 118), and, therefore, may be referred to as “highly doped” (HD) regions. Even when doped to realize threshold voltage tuning as described herein, the channel portions of transistors typically include semiconductor materials with doping concentrations significantly smaller than those of the source region 116 and the drain region 118.

The source region 116 and the drain region 118 of the transistor 120 may generally be formed using either an implantation/diffusion process or an etching/deposition process. In the former process, dopants such as boron, aluminum, antimony, phosphorous, or arsenic may be ion-implanted into the channel material 102 to form the source and drain regions. An annealing process that activates the dopants and causes them to diffuse further into the channel material 102 may follow the ion implantation process. In the latter process, portions of the channel material 102 may first be etched to form recesses at the locations of the future source region 116 and drain region 118. An epitaxial deposition process may then be carried out to fill the recesses with material that is used to fabricate the source region 116 and the drain region 118. In some implementations, the source region 116 and the drain region 118 may be fabricated using a silicon alloy such as silicon germanium or silicon carbide. In some implementations, the epitaxially deposited silicon alloy may be doped in situ with dopants such as boron, arsenic, or phosphorous. In further embodiments, the source region 116 and the drain region 118 may be formed using one or more alternate semiconductor materials such as germanium or a group III-V material or alloy. And in further embodiments, one or more layers of metal and/or metal alloys may be used to form the source region 116 and the drain region 118. Because, as is common in the field of FETs, designations of source and drain are often interchangeable, the source region 116 and the drain region 118 of the transistor 120 may simply be referred to herein as a first source or drain (S/D) region and a second S/D region.

FIG. 3 depicts a transistor 120 including a transistor gate stack 100 and having a single “top” gate provided by the gate electrode material 108 and the gate dielectric stack 110 (which includes the high-k dielectric 106 and the insulator material 104). The gate dielectric stack 110 may be disposed between the gate electrode material 108 and the channel material 102. The gate dielectric stack 110 may border the channel material 102; in particular, the insulator material 104 may contact the channel material 102 without any intervening material in some embodiments. In the embodiment of FIG. 3, the gate stack 100 is shown as disposed on a support 122. The transistor 120 may include a source region 116 and a drain region 118 disposed on the support 122, with the insulator material 104 disposed between the source region 116 and the drain region 118 so that at least some of the insulator material 104 is coplanar with at least some of the source region 116 and the drain region 118. As discussed above, in some embodiments, the support 122 of FIG. 3 may include a semiconductor material and ILD disposed between the semiconductor material and the source region 116, the channel material 102, and the drain region 118, to electrically isolate the semiconductor material of the support 122 from the source region 116, the channel material 102, and the drain region 118. In some embodiments, the insulator material 104, the high-k dielectric 106, and/or the gate electrode material 108 may conform around the source region 116 and/or the drain region 118.

FIG. 4 depicts a transistor 120 including a transistor gate stack 100 and having a single “bottom” gate provided by the gate electrode material 108 and the gate dielectric stack 110 (which includes the high-k dielectric 106 and the insulator material 104). The gate dielectric stack 110 may be disposed between the gate electrode material 108 and the channel material 102. The gate dielectric stack 110 may border the channel material 102; in particular, the insulator material 104 may contact the channel material 102 without any intervening material in some embodiments. In the embodiment of FIG. 4, the gate stack 100 is shown as disposed on a support 122 in an orientation “upside down” to the one illustrated in FIG. 2; that is, the gate electrode material 108 may be disposed between the support 122 and the channel material 102. The transistor 120 may include a source region 116 and a drain region 118 disposed on the channel material 102 such that the source region 116 and the drain region 118 are not coplanar with the channel material 102.

FIG. 5 depicts a transistor 120 including a transistor gate stack 100 and having a single “bottom” gate provided by the gate electrode material 108 and the gate dielectric stack 110 (which includes the high-k dielectric 106 and the insulator material 104). The gate dielectric stack 110 may be disposed between the gate electrode material 108 and the channel material 102. The gate dielectric stack 110 may border the channel material 102; in particular, the insulator material 104 may contact the channel material 102 without any intervening material in some embodiments. In the embodiment of FIG. 5, the gate stack 100 is shown as disposed on a support 122 in an orientation “upside down” to the one illustrated in FIG. 2; that is, the gate electrode material 108 may be disposed between the support 122 and the channel material 102. The transistor 120 may include a source region 116 and a drain region 118 disposed on the channel material 102 such that at least some of the source region 116 and at least some of the drain region 118 are coplanar with at least some of the channel material 102. In some embodiments, the source region 116 and the drain region 118 may each be disposed between some of the channel material 102 and the support 122, as illustrated in FIG. 5, while in other embodiments, the channel material 102 may not extend “above” the source region 116 or the drain region 118. In some embodiments, the channel material 102 may conform around the source region 116 and/or the drain region 118.

FIG. 6 depicts a double-gate transistor 120 including two transistor gate stacks 100-1 and 100-2 and having “bottom” and “top” gates provided by the gate electrode material 108-1/gate dielectric stack 110-1 and the gate electrode material 108-2/gate dielectric stack 110-2, respectively. The gate dielectric stacks 110-1 and 110-2 may include high-k dielectrics 106-1 and 106-2, and insulator materials 104-1 and 104-2, respectively. Each gate dielectric stack 110 may be disposed between the corresponding gate electrode material 108 and the channel material 102. Each gate dielectric stack 110 may border the channel material 102; in particular, the insulator material 104-1 and 104-2 may contact the channel material 102 without any intervening material in some embodiments. The transistor 120 may include a source region 116 and a drain region 118 disposed proximate to the channel material 102. In the embodiment illustrated in FIG. 6, the source region 116 and the drain region 118 are disposed on the insulator material 104-2, and the high-k dielectric 106-2 is disposed conformably around the source region 116, the insulator material 104-2, and the drain region 118. The gate electrode material 108-2 is disposed on the high-k dielectric 106-2. In the embodiment of FIG. 6, at least some of the source region 116 and at least some of the drain region 118 are coplanar with at least some of the high-k dielectric 106-2.

FIG. 7 depicts a double-gate transistor 120 including two transistor gate stacks 100-1 and 100-2 and having “bottom” and “top” gates provided by the gate electrode material 108-1/gate dielectric stack 110-1 and the gate electrode material 108-2/gate dielectric stack 110-2, respectively. Each gate dielectric stack 110 may include a high-k dielectric 106 and an insulator material 104. Each gate dielectric stack 110 may be disposed between the corresponding gate electrode material 108 and the channel material 102. Each gate dielectric stack 110 may border the channel material 102; in particular, the insulator material 104-1 and 104-2 may contact the channel material 102 without any intervening material in some embodiments. The transistor 120 may include a source region 116 and a drain region 118 disposed proximate to the channel material 102. In the embodiment illustrated in FIG. 7, the source region 116 and the drain region 118 are coplanar with the channel material 102, and disposed between the high-k dielectrics 106-1 and 106-2. The relative arrangement of the source region 116, the drain region 118, and the channel material 102 may take the form of any of the embodiments discussed above with reference to FIG. 2.

FIGS. 8A and 8B are perspective and cross-sectional side views, respectively, of an example tri-gate transistor 120 including a transistor gate stack 100, in accordance with various embodiments. The transistor 120 of FIGS. 8A and 8B may include a channel material 102, and a gate stack 100 including a gate electrode material 108, a high-k dielectric 106 and an insulator material 104. The insulator material 104 may be disposed between the high-k dielectric 106 and the channel material 102 (e.g., insulator material 104 may be in contact with the channel material 102). In the tri-gate transistor 120 illustrated in FIGS. 8A and 8B, a fin 132 formed of a semiconductor material may extend from a base 140 of the semiconductor material. An oxide material 130 may be disposed on either side of the fin 132. In some embodiments, the oxide material 130 may include any of the materials discussed herein with reference to the high-k dielectric 106.

The gate stack 100 may wrap around the fin 132 as shown, with the channel material 102 corresponding to the portion of the fin 132 wrapped by the gate stack 100. In particular, the insulator material 104 may wrap around the channel material 102 of the fin 132, the high-k dielectric 106 may wrap around the insulator material 104, and the gate electrode material 108 may wrap around the high-k dielectric 106. The fin 132 may include a source region 116 and a drain region 118 on either side of the gate stack 100, as shown. The composition of the channel material 102, the source region 116, and a drain region 118 may take the form of any of the embodiments disclosed herein, or known in the art. Although the fin 132 illustrated in FIGS. 8A and 8B is shown as having a rectangular cross section, the fin 132 may instead have a cross section that is rounded or sloped at the “top” of the fin 132, and the gate stack 100 may conform to this rounded or sloped fin 132. In use, the tri-gate transistor 120 may form conducting channels on three “sides” of the fin 132, potentially improving performance relative to single-gate transistors (which may form conducting channels on one “side” of the channel material 102) and double-gate transistors (which may form conducting channels on two “sides” of the channel material 102).

FIGS. 9A and 9B are perspective and cross-sectional side views, respectively, of an example all-around gate transistor 120 including a transistor gate stack 100, in accordance with various embodiments. The transistor 120 of FIGS. 9A and 9B may include a channel material 102, and a gate stack 100 including a gate electrode material 108, a high-k dielectric 106 and an insulator material 104. The insulator material 104 may be disposed between the high-k dielectric 106 and the channel material 102 (e.g., the insulator material 104 may be in contact with the channel material 102). In the all-around gate transistor 120 illustrated in FIGS. 9A and 9B, a wire 136 formed of a semiconductor material may extend above a substrate 134 and a layer of oxide material 130. The wire 136 may take the form of a nanowire or nanoribbon, for example. The gate stack 100 may wrap entirely or almost entirely around the wire 136, as shown, with the channel material 102 corresponding to the portion of the wire 136 wrapped by the gate stack 100. In particular, the insulator material 104 may wrap around the channel material 102 of the fin 132, the high-k dielectric 106 may wrap around the insulator material 104, and the gate electrode material 108 may wrap around the high-k dielectric 106. In some embodiments, the gate stack 100 may fully encircle the wire 136. The wire 136 may include a source region 116 and a drain region 118 on either side of the gate stack 100, as shown. The composition of the channel material 102, the source region 116, and a drain region 118 may take the form of any of the embodiments disclosed herein, or known in the art. Although the wire 136 illustrated in FIGS. 9A and 9B is shown as having a rectangular cross section, the wire 136 may instead have a cross section that is rounded or otherwise irregularly shaped, and the gate stack 100 may conform to the shape of the wire 136. In use, the tri-gate transistor 120 may form conducting channels on more than three “sides” of the wire 136, potentially improving performance relative to tri-gate transistors. Although FIGS. 9A and 9B depict an embodiment in which the longitudinal axis of the wire 136 runs substantially parallel to a plane of the oxide material 130 (and a plane of the substrate 134), this need not be the case; in other embodiments, for example, the wire 136 may be oriented “vertically” so as to be perpendicular to a plane of the oxide 130 (or plane of the substrate 134).

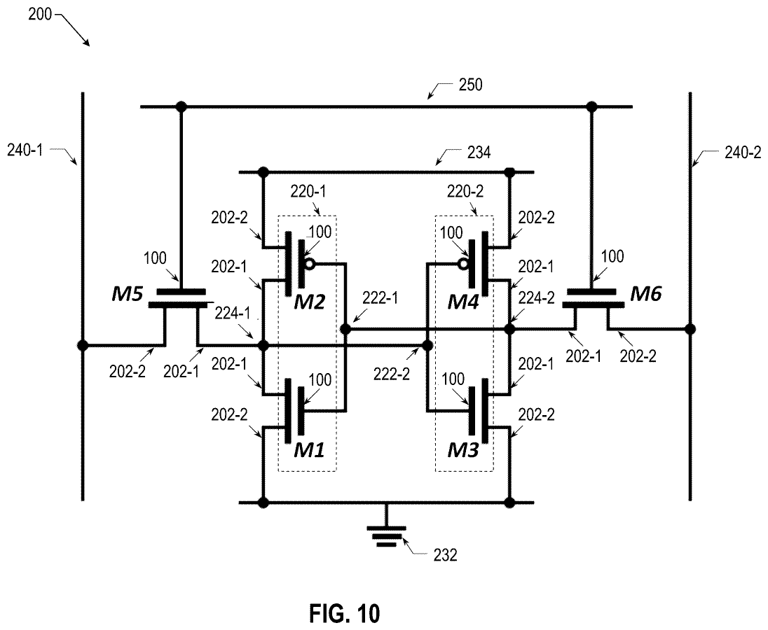

FIG. 10 provides an electric circuit diagram of an example SRAM cell 200, according to some embodiments of the present disclosure. As shown in FIG. 10, the SRAM cell 200 may includes transistors M1-M4 for storing a bit value or a memory state (e.g., logic “1” or “0”) of the cell, and two access transistors, M5 and M6, for controlling access to the cell (e.g., access to write information to the cell or access to read information from the cell 200). Each of transistors M1-M6 may be a transistor 120 according to any embodiments described herein, e.g., may be a transistor 120 as shown in any of FIGS. 2-9) and, to illustrate that, FIG. 10 labels the gate stack 100 for each of transistors M1-M6. Furthermore, because, as described above, designations of source and drain are often interchangeable, FIG. 10 illustrates a first S/D region 202-1 and a second S/D region 202-2 for each of transistors M1-M6, where one of the first S/D region 202-1 and the second S/D region may be the source region 116 and the other one may be the drain region 118. In the description of FIG. 10 and other similar descriptions presented herein, when element A is described to be coupled to element B, the term “coupled” covers an embodiment where element A is directly connected to element B. For example, a description that the gate stack 100 of transistor M1 may be coupled to the gate stack 100 of transistor M2 covers an embodiment where the gate stack 100 of transistor M1 is directly connected to the gate stack 100 of transistor M2.

FIG. 10 illustrates some transistors as N-type transistors (i.e., transistors M1, M3, M5, and M6) and other transistors as P-type transistors (i.e., transistors M2 and M4), using conventional electric circuit diagram notation for such transistors. However, in other embodiments of the SRAM cell 200, this notation may be reversed (i.e., transistors M1, M3, M5, and M6 could be P-type transistors and transistors M2 and M4 could be N-type transistors), while also reversing the designation of the ground voltage 232 and the supply voltage 234 shown in FIG. 10, all of which embodiments being within the scope of the present disclosure.

In the SRAM cell 200, each bit may be stored on four transistors (M1, M2, M3, M4) that form two cross-coupled inverters 220, each having an input 222 and an output 224. The first inverter 220-1 may be formed by transistor M1 and transistor M2, while the second inverter 220-2 may be formed by transistor M3 and transistor M4. As shown in FIG. 10, the gate stack 100 of transistor M1 may be coupled to the gate stack 100 of transistor M2, and both of these gate stacks may be coupled to the input 222-1 of the first inverter 220-1. On the other hand, the first S/D region 202-1 of transistor M1 may be coupled to the first S/D region 202-1 of transistor M2, and both of these first S/D regions 202-1 may be coupled to the output 224-1 of the first inverter 220-1. Similarly, for the second inverter 220-2, the gate stack 100 of transistor M3 may be coupled to the gate stack 100 of transistor M4, and both of these gate stacks may be coupled to the input 222-2 of the second inverter 220-2, while the first S/D region 202-1 of transistor M3 may be coupled to the first S/D region 202-1 of transistor M4, and both of these first S/D regions 202-1 may be coupled to the output 224-2 of the second inverter 220-2. As also shown in FIG. 10, when transistors M1 and M3 are N-type transistors and when transistors M2 and M4 are P-type transistors as illustrated in FIG. 10, the second S/D regions 202-2 of transistors M1 and M3 may be coupled to a ground voltage 232, while the second S/D regions 202-2 of transistors M2 and M4 may be coupled to a supply voltage 234, e.g., VDD. In the embodiments of the SRAM cell 200 where the N-type transistors shown in FIG. 10 are replaced with P-type transistors and vice versa, the designation of the ground voltage 232 and the supply voltage 234 would be reversed as well.

The four transistors M1-M4 in such configuration form a stable storage cell for storing a bit value of 0 or 1. As further shown in FIG. 10, two additional access transistors, M5 and M6, may serve to control the access to the storage cell of transistors M1-M4 during read and write operations. As shown in FIG. 10, the first S/D region 202-1 of the access transistor M5 may be coupled to the output 224-1 of the first inverter 220-1. Phrased differently, the first S/D region 202-1 of the access transistor M5 may be coupled to each of the first S/D region 202-1 of transistor M1 and the first S/D region 202-1 of transistor M2. The second S/D region 202-2 of the access transistor M5 may be coupled to a first bitline (BL) 240-1. Thus, each of the first S/D region 202-1 of transistor M1 and the first S/D region 202-1 of transistor M2 may be coupled to the first BL 240-1 (e.g., via the access transistor M5). The gate stack 100 of the access transistor M5 may be coupled to a wordline (WL) 250. As further shown in FIG. 10, the first S/D region 202-1 of the access transistor M6 may be coupled to the output 224-2 of the second inverter 220-2. Phrased differently, the first S/D region 202-1 of the access transistor M6 may be coupled to each of the first S/D region 202-1 of transistor M3 and the first S/D region 202-1 of transistor M4. The second S/D region 202-2 of the access transistor M6 may be coupled to a second BL 240-2. Thus, each of the first S/D region 202-1 of transistor M3 and the first S/D region 202-1 of transistor M4 may be coupled to the second BL 240-1 (e.g., via the access transistor M6). The gate stack 100 of the access transistor M6 may be coupled to the WL 250. Thus, the gate stacks 100 of both of the access transistors M5 and M6 may be coupled to a single, shared, WL, the WL 250. As also shown in FIG. 10, the input 222-1 of the first inverter 220-1 may be coupled to the first S/D region 202-1 of the access transistor M6, while the input 222-2 of the second inverter 220-2 may be coupled to the first S/D region 202-1 of the access transistor M5. In other words, each of the gate stack 100 of transistor M1 and the gate stack 100 of transistor M2 may be coupled to the first S/D region 202-1 of the access transistor M6, while each of the gate stack 100 of transistor M3 and the gate stack 100 of transistor M4 may be coupled to the first S/D region 202-1 of the access transistor M5. Phrased differently, each of the gate stack 100 of transistor M1 and the gate stack 100 of transistor M2 may be coupled to the second BL 240-2 (e.g., via the access transistor M6), while each of the gate stack 100 of transistor M3 and the gate stack 100 of transistor M4 may be coupled to the first BL 240-1 (e.g., via the access transistor M5).

The WL 250 and the first and second BLs 240 may be used together to read and program (i.e., write to) the SRAM cell 200. In particular, access to the cell may be enabled by the WL 250 which controls the two access transistors M5 and M6 which, in turn, control whether the cell 200 should be connected to the BLs 240-1 and 240-2. During operation of the SRAM cell 200, a signal on the first BL 240-1 may be complementary to a signal on the second BL 240-2. The two BLs 240 may be used to transfer data for both read and write operations. In other embodiments of the SRAM cell 200, only a single BL 240 may be used, instead of two BLs 240-1 and 240-2 (i.e., the signal on the BL 240-1 and BL 240-2 may be the same), although having one signal BL and one inverse, such as the two BLs 240, may help improve noise margins.

During read accesses, the BLs 240 are actively driven high and low by the inverters 220 in the SRAM cell 200. This may improve SRAM bandwidth compared to DRAM. The symmetric structure of the SRAMs cell 200 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, i.e., higher bits followed by lower bits, over the same package pins in order to keep their size and cost down.

Each of the WL 250 and the BLs 240, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

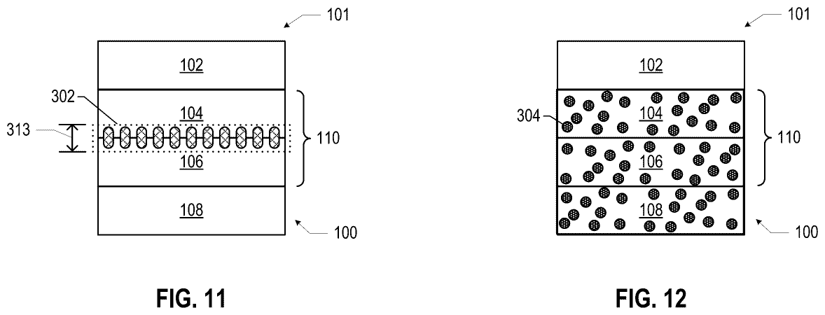

As the foregoing illustrates, transistors M2 and M4 of the SRAM cell 200 are transistors of one type, while transistors M1, M3, M5, and M6 are transistors of the other type. In some embodiments, the gate stack 100 of one or more of the transistors of the SRAM cell 200 that are of one type could be modified, from the gate stack 100 of FIG. 1, to be as shown either in FIG. 11 or in FIG. 12, while all of the transistors of the SRAM cell 200 that are of the other type would have the gate stack 100 as shown in FIG. 1. For example, in some embodiments, the gate stacks 100 of the transistors M2 and/or M4 may be as shown in FIG. 11 or FIG. 12, while the gate stacks 100 of the transistors M1, M3, M5, and M6 may be as shown in FIG. 1. In other embodiments, the gate stacks 100 of one or more (e.g., all) of the transistors M1, M3, M5, and M6 may be as shown in FIG. 11 or FIG. 12, while the gate stacks 100 of the transistors M2 and M4 may be as shown in FIG. 1.

FIG. 11 is a cross-sectional side view of a transistor gate-channel arrangement 101 including a transistor gate stack 100 with a dipole layer 302, in accordance with various embodiments. As shown in FIG. 11, the dipole layer 302 may be between the high-k dielectric 106 and the channel material 102, e.g., between the high-k dielectric 106 and the insulator material 104. In some embodiments, the dipole layer 302 may be at an interface between the high-k dielectric 106 and the insulator material 104, as shown in FIG. 11. In some embodiments, the dipole material 302 may be a dielectric/insulator material and may include a metal. The metal may be lanthanum, aluminum, or magnesium. In some embodiments, the dipole material 302 may include a metal and further include oxygen, e.g., it may be a metal oxide. In some embodiments, the dipole material 302 may include a metal and further include oxygen and nitrogen, e.g., it may be a metal oxynitride. In various embodiments, a thickness 313 of the dipole material may be smaller than about 1 nanometer, e.g., smaller than about 5 angstrom, e.g., smaller than about 3 angstrom or smaller than about 2 angstrom.

FIG. 12 is a cross-sectional side view of a transistor gate-channel arrangement 101 including a transistor gate stack 100 with implanted halogens 304, in accordance with various embodiments. The halogens 304 may, e.g., include fluorine particles. In some embodiments, the halogens 304 may be implanted in each of the insulator material 104, the high-k dielectric 106, and the gate electrode material 108, as shown in FIG. 12. However, in other embodiments, this may be different. For example, in some embodiments, the halogens 304 may be implanted in the high-k dielectric 106 but be absent in the insulator material 104 and in the gate electrode material 108. In some embodiments, the halogens 304 may be implanted in the high-k dielectric 106 and in the gate electrode material 108 but be absent in the insulator material 104. In some embodiments, the halogens 304 may be implanted in the gate electrode material 108 but be absent in the insulator material 104 and in the high-k dielectric 106. In some embodiments, the halogens 304 may be implanted in the insulator material 104 but be absent in the gate electrode material 108 and in the high-k dielectric 106. In some embodiments, a concentration of the halogens 304 may increase further away from the channel material 102. For example, the concentration of the halogens 304 may be greatest in the gate electrode material 108 and gradually decrease in portions of the gate stack 100 closer to the channel material 102. Alternatively, the concentration of the halogens 304 may be greatest in a portion of the high-k dielectric 106 that is closest to the gate electrode material 108 and gradually decrease in portions of the gate stack 100 closer to the channel material 102. In some embodiments, an average concentration of the halogens 304 in the gate stack 100 may be at least about 10¹⁵ atoms per cubic centimeter, e.g., at least about 10¹⁷ atoms per cubic centimeter, or at least about 10¹⁹ atoms per cubic centimeter.

Although FIG. 11 and FIG. 12 illustrate the dipole layer 302 and the halogens 304 separately from one another, in some embodiments, a gate stack 100 that includes the dipole layer 302 may also include the halogens 304. Furthermore, in some embodiments, if one of the transistors of the SRAM cell 200 includes the gate stack 100 with the dipole layer 302, another one of the transistors of the same type in the SRAM cell 200 may include the halogens 304.

IC structures with transistor gate-channel arrangements for SRAM as described herein, in particular IC structures with SRAM having transistor gate-channel arrangements with dipole materials or halogens in one or more transistors of one type but in none of the transistors of the other type, may be included in any suitable electronic component or electronic device. FIGS. 13-17 illustrate various examples of apparatuses that may include one or more of the IC structures with transistor gate-channel arrangements for SRAM disclosed herein.

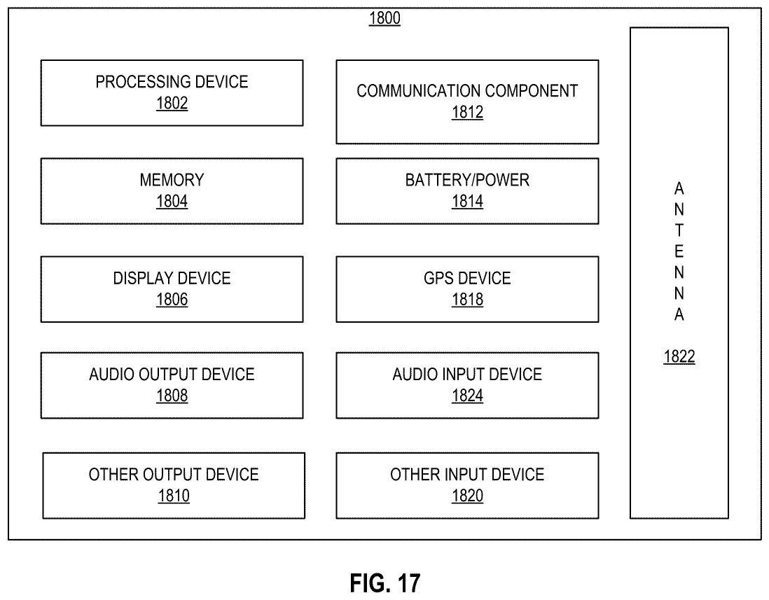

FIG. 13 is a top view of a wafer 1500 and dies 1502 that may include one or more IC structures with transistor gate-channel arrangements for SRAM in accordance with any of the embodiments disclosed herein, e.g., one or more IC structures that include the SRAM cell 200 with dipole materials 302 and/or halogens 304 in one or more transistors of one type but in none of the transistors of the other type, where any of the transistors may be implemented as any of the transistors 120 described herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures with transistor gate-channel arrangements for SRAM and/or supporting circuitry to route electrical signals to the transistors of the one or more IC structures with transistor gate-channel arrangements for SRAM, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 17) or other logic that is configured to store information in the memory devices or execute instructions stored in the memory array.

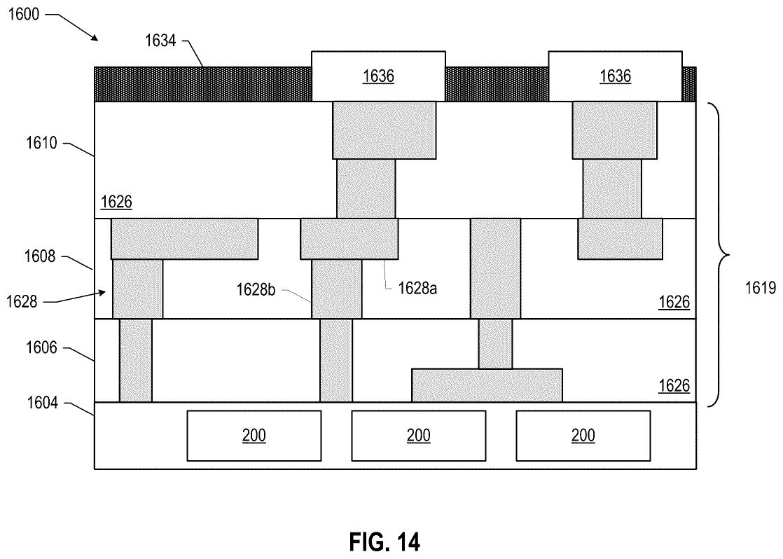

FIG. 14 is a side, cross-sectional view of an IC device 1600 that may include one or more IC structures 100 in accordance with any of the embodiments disclosed herein. One or more of the IC devices 1600 may be included in one or more dies 1502 (FIG. 13). The IC device 1600 may include a device region 1604 including one or more SRAM cells 200 disclosed herein, e.g., one or more SRAM cells 200 with dipole materials 302 and/or halogens 304 in one or more transistors of one type but in none of the transistors of the other type, where any of the transistors may be implemented as any of the transistors 120 described herein. The device region 1604 may further include electrical contacts to the gate and S/D contacts of the transistors included in the device region 1604.

Electrical signals, such as power and/or input/output (I/O) signals, may be routed to and/or from the devices (e.g., the transistors) of the device region 1604 through one or more interconnect layers disposed on the device region 1604 (illustrated in FIG. 14 as interconnect layers 1606, 1608, and 1610). For example, electrically conductive features of the device region 1604 (e.g., the gate electrode materials 108) may be electrically coupled with the interconnect structures 1628 of the interconnect layers 1606, 1608, and 1610. The one or more interconnect layers 1606, 1608, and 1610 may form a metallization stack (also referred to as an “ILD stack”) 1619 of the IC device 1600.

The interconnect structures 1628 may be arranged within the interconnect layers 1606, 1608, and 1610 to route electrical signals according to a wide variety of designs (in particular, the arrangement is not limited to the particular configuration of interconnect structures 1628 depicted in FIG. 14). Although a particular number of interconnect layers 1606, 1608, and 1610 is depicted in FIG. 14, embodiments of the present disclosure include IC structures having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the support 102 upon which the device region 1604 is formed. For example, the lines 1628a may route electrical signals in a direction in and out of the page from the perspective of FIG. 14. The vias 1628b may be arranged to route electrical signals in a direction of a plane that is substantially perpendicular to the surface of the support 102 upon which the device region 1604 is formed. In some embodiments, the vias 1628b may electrically couple lines 1628a of different interconnect layers 1606, 1608, and 1610 together.

The interconnect layers 1606, 1608, and 1610 may include a dielectric material 1626 disposed between the interconnect structures 1628, as shown in FIG. 14. In some embodiments, the dielectric material 1626 disposed between the interconnect structures 1628 in different ones of the interconnect layers 1606, 1608, and 1610 may have different compositions; in other embodiments, the composition of the dielectric material 1626 between different interconnect layers 1606, 1608, and 1610 may be the same.

A first interconnect layer 1606 may be formed above the device region 1604. In some embodiments, the first interconnect layer 1606 may include lines 1628a and/or vias 1628b, as shown. The lines 1628a of the first interconnect layer 1606 may be coupled with contacts (e.g., contacts to the S/D regions 114 of the IC structures 100) of the device region 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device region 1604) may be thicker.

The IC device 1600 may include a solder resist material 1634 (e.g., polyimide or similar material) and one or more conductive contacts 1636 formed on the interconnect layers 1606, 1608, and 1610. In FIG. 14, the conductive contacts 1636 are illustrated as taking the form of bond pads. The conductive contacts 1636 may be electrically coupled with the interconnect structures 1628 and configured to route the electrical signals of the transistor(s) of the device region 1604 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606, 1608, and 1610; for example, the conductive contacts 1636 may include other analogous features (e.g., posts) that route the electrical signals to external components.

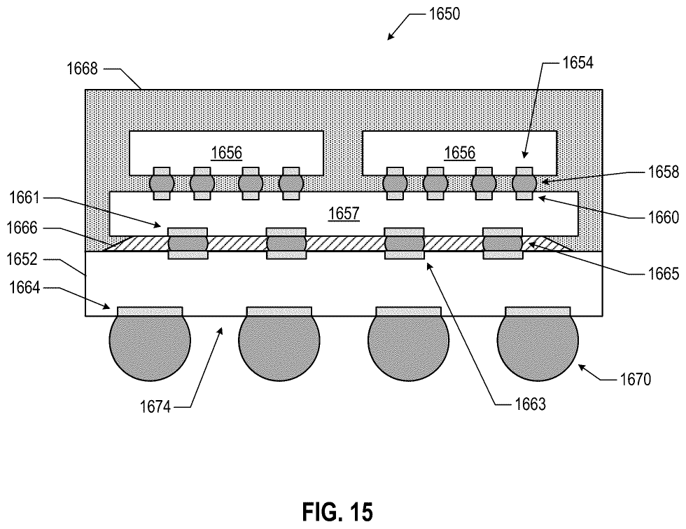

FIG. 15 is a side, cross-sectional view of an example IC package 1650 that may include one or more IC structures with transistor gate-channel arrangements for SRAM in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnects 1628 discussed above with reference to FIG. 14.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 15 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 15 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

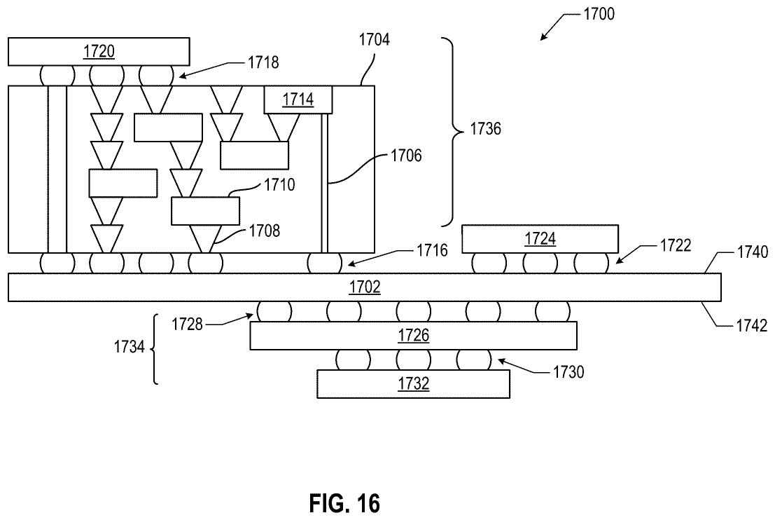

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 15 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 16.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory).

Although the IC package 1650 illustrated in FIG. 15 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 15, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 16 is a side, cross-sectional view of an IC device assembly 1700 that may include one or more IC packages or other electronic components (e.g., a die) including one or more IC structures with transistor gate-channel arrangements for SRAM in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 15 (e.g., may include one or more IC structures 100).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 16 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 16), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 16, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 13), an IC device (e.g., the IC device 1600 of FIG. 14), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 16, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 16 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 17 is a block diagram of an example electrical device 1800 that may include one or more IC structures with transistor gate-channel arrangements for SRAM in accordance with any of the embodiments disclosed herein. For example, any suitable ones of the components of the electrical device 1800 may include one or more of the IC device assemblies 1700, IC packages 1650, IC structures 1600, or dies 1502 disclosed herein. A number of components are illustrated in FIG. 17 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 17, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure that includes: a memory cell including a plurality of transistors including transistors of a first type and transistors of a second type, wherein one of the first type and the second type is an N-type and another one of the first type and the second type is a P-type, and wherein an individual transistor of the plurality of transistors includes a channel material and a transistor gate stack, the transistor gate stack including a gate electrode material and a high-k dielectric between the gate electrode material and the channel material; and a dipole material between the high-k dielectric and the channel material in one or more of the transistors of the first type, wherein the dipole material is absent between the high-k dielectric and the channel material in all of the transistors of the second type.

Example 2 provides the IC structure according to example 1, wherein: the plurality of transistors includes a transistor M1, a transistor M2, a transistor M3, a transistor M4, a transistor M5, and a transistor M6; the transistors M2 and M4 are transistors of the first type; and the transistors M1, M3, M5, and M6 are transistors of the second type.

Example 3 provides the IC structure according to example 1, wherein: the plurality of transistors includes a transistor M1, a transistor M2, a transistor M3, a transistor M4, a transistor M5, and a transistor M6; the transistors M1, M3, M5, and M6 are transistors of the first type; and the transistors M2 and M4 are transistors of the second type.

Example 4 provides the IC structure according to any one of examples 1-3, wherein the dipole material includes lanthanum, aluminum, or magnesium.

Example 5 provides the IC structure according to any one of examples 1-4, wherein the dipole material is a dielectric material and includes a metal.

Example 6 provides the IC structure according to example 5, wherein the metal is lanthanum, aluminum, or magnesium.

Example 7 provides the IC structure according to any one of examples 4-6, wherein the dipole material further includes oxygen.

Example 8 provides the IC structure according to any one of examples 4-7, wherein the dipole material further includes nitrogen.

Example 9 provides the IC structure according to any one of examples 1-8, wherein a thickness of the dipole material is smaller than about 5 angstrom, e.g., smaller than about 3 angstrom or smaller than about 2 angstrom.

Example 10 provides the IC structure according to any one of examples 1-9, wherein the transistor gate stack of the individual transistor further includes an insulator material between the high-k dielectric and the channel material, the dipole material between the high-k dielectric and the channel material in the one or more of the transistors of the first type is between the high-k dielectric and the insulator material, and a dielectric constant of the insulator material is lower than a dielectric constant of the high-k dielectric.

Example 11 provides an IC structure that includes a memory cell including a plurality of transistors including transistors of a first type and transistors of a second type, wherein one of the first type and the second type is an N-type and another one of the first type and the second type is a P-type, and wherein an individual transistor of the plurality of transistors includes a channel material and a transistor gate stack, the transistor gate stack including a gate electrode material and a high-k dielectric between the gate electrode material and the channel material; and halogens in at least a portion of the transistor gate stack in one or more of the transistors of the first type, wherein the halogens are absent from the transistor gate stack in all of the transistors of the second type.

Example 12 provides the IC structure according to example 11, wherein the plurality of transistors includes a transistor M1, a transistor M2, a transistor M3, a transistor M4, a transistor M5, and a transistor M6; the transistors M2 and M4 are transistors of the first type; and the transistors M1, M3, M5, and M6 are transistors of the second type.

Example 13 provides the IC structure according to example 11, wherein the plurality of transistors includes a transistor M1, a transistor M2, a transistor M3, a transistor M4, a transistor M5, and a transistor M6; the transistors M1, M3, M5, and M6 are transistors of the first type; and the transistors M2 and M4 are transistors of the second type.

Example 14 provides the IC structure according to any one of examples 11-13, wherein the halogens include fluorine.

Example 15 provides the IC structure according to any one of examples 11-14, wherein the portion of the transistor gate stack that includes the halogens in one or more of the transistors of the first type includes the high-k dielectric.

Example 16 provides the IC structure according to any one of examples 11-15, wherein the portion of the transistor gate stack that includes the halogens in one or more of the transistors of the first type includes the gate electrode material.

Example 17 provides the IC structure according to any one of examples 11-16, wherein the transistor gate stack of the individual transistor further includes an insulator material between the high-k dielectric and the channel material, a dielectric constant of the insulator material is lower than a dielectric constant of the high-k dielectric, and the portion of the transistor gate stack that includes the halogens in one or more of the transistors of the first type includes the insulator material.

Example 18 provides the IC structure according to any one of examples 11-17, wherein a concentration of the halogens increases further away from the channel material.

Example 19 provides the IC structure according to any one of examples 11-18, wherein an average concentration of the halogens in the at least a portion of the transistor gate stack in the one or more of the transistors of the first type is at least about 10¹⁵ atoms per cubic centimeter, e.g., at least about 10¹⁷ atoms per cubic centimeter, or at least about 10¹⁹ atoms per cubic centimeter.

Example 20 provides the IC structure according to any one of examples 11-19, further including a dipole material between the high-k dielectric and the channel material in the one or more of the transistors of the first type, wherein the dipole material is absent between the high-k dielectric and the channel material in all of the transistors of the second type.

Example 21 provides an IC structure that includes a memory cell, including a first inverter including a transistor M1 and a transistor M2, and a second inverter including a transistor M3 and a transistor M4, wherein the second inverter is coupled to the first inverter, the transistors M1 and M3 are transistors of a first type, the transistors M2 and M4 are transistors of a second type, one of the first type and the second type is an N-type and another one of the first type and the second type is a P-type, a gate stack of at least one of the transistors M1 and M3 includes either a dipole material or halogens, and none of the gate stacks of the transistors M2 and M4 include the dipole material or the halogens.

Example 22 provides the IC structure according to example 21, wherein the gate stack of each of the transistors M1 and M3 includes either the dipole material or the halogens.

Example 23 provides an IC package that includes an IC die including an IC structure according to any one of examples 1-22; and a further IC component, coupled to the IC die.

Example 24 provides the IC package according to example 23, where the further IC component includes a package substrate or an interposer.

Example 25 provides the IC package according to example 23, where the further IC component includes a further IC die.

Example 26 provides a computing device that includes a carrier substrate and an IC structure coupled to the carrier substrate, where the IC structure is an IC structure according to any one of examples 1-22, or the IC structure is included in the IC package according to any one of examples 23-25.

Example 27 provides the computing device according to example 26, where the computing device is a wearable or handheld computing device.

Example 28 provides the computing device according to examples 26 or 27, where the computing device further includes one or more communication chips.

Example 29 provides the computing device according to any one of examples 26-28, where the computing device further includes an antenna.

Example 30 provides the computing device according to any one of examples 26-29, where the carrier substrate is a motherboard.

Example 31 provides the IC structure according to any one of examples 1-22, wherein the IC structure includes or is a part of a central processing unit.

Example 32 provides the IC structure according to any one of examples 1-31, wherein the IC structure includes or is a part of a memory device.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a memory cell comprising a plurality of transistors comprising transistors of a first type and transistors of a second type, wherein one of the first type and the second type is an N-type and another one of the first type and the second type is a P-type, and wherein an individual transistor of the plurality of transistors includes a channel material and a transistor gate stack, the transistor gate stack comprising a gate electrode material and a high-k dielectric between the gate electrode material and the channel material; and
a dipole material between the high-k dielectric and the channel material in one or more of the transistors of the first type,
wherein the dipole material is absent between the high-k dielectric and the channel material in all of the transistors of the second type.

2. The IC structure according to claim 1, wherein:
the memory cell is a static random-access memory cell,
the plurality of transistors includes a transistor M1, a transistor M2, a transistor M3, a transistor M4, a transistor M5, and a transistor M6, and
either the transistors M2 and M4 are transistors of the first type and the transistors M1, M3, M5, and M6 are transistors of the second type,
or the transistors M1, M3, M5, and M6 are transistors of the first type, and the transistors M2 and M4 are transistors of the second type.

3. The IC structure according to claim 1, wherein the dipole material is a dielectric material and includes a metal.

4. The IC structure according to claim 3, wherein the metal is lanthanum, aluminum, or magnesium.

5. The IC structure according to claim 3, wherein the dipole material further includes oxygen.

6. The IC structure according to claim 5, wherein the dipole material further includes nitrogen.

7. The IC structure according to claim 1, wherein a thickness of the dipole material is smaller than about 3 angstrom.

8. The IC structure according to claim 1, wherein:
the transistor gate stack of the individual transistor further includes an insulator material between the high-k dielectric and the channel material,
the dipole material between the high-k dielectric and the channel material in the one or more of the transistors of the first type is between the high-k dielectric and the insulator material, and
a dielectric constant of the insulator material is lower than a dielectric constant of the high-k dielectric.

9. An integrated circuit (IC) structure, comprising:
a memory cell comprising a plurality of transistors comprising transistors of a first type and transistors of a second type, wherein one of the first type and the second type is an N-type and another one of the first type and the second type is a P-type, and wherein an individual transistor of the plurality of transistors includes a channel material and a transistor gate stack, the transistor gate stack comprising a gate electrode material and a high-k dielectric between the gate electrode material and the channel material; and
halogens in at least a portion of the transistor gate stack in one or more of the transistors of the first type,
wherein the halogens are absent from the transistor gate stack in all of the transistors of the second type.

10. The IC structure according to claim 9, wherein:
the memory cell is a static random-access memory cell,
the plurality of transistors includes a transistor M1, a transistor M2, a transistor M3, a transistor M4, a transistor M5, and a transistor M6, and
either the transistors M2 and M4 are transistors of the first type, and the transistors M1, M3, M5, and M6 are transistors of the second type,
or the transistors M1, M3, M5, and M6 are transistors of the first type, and the transistors M2 and M4 are transistors of the second type.

11. The IC structure according to claim 9, wherein:
the memory cell is a static random-access memory cell comprising a first inverter and a second inverter cross-coupled with the first inverter,
the plurality of transistors includes a transistor M1, a transistor M2, a transistor M3, a transistor M4,
the first inverter includes the transistors M1 and M2,
the second inverter includes the transistors M3 and M4, and
the transistors M1 and M3 are transistors of the first type and the transistors M2 and M4 are transistors of the second type.

12. The IC structure according to claim 9, wherein the halogens include fluorine.

13. The IC structure according to claim 9, wherein the portion of the transistor gate stack that includes the halogens in one or more of the transistors of the first type includes the high-k dielectric.

14. The IC structure according to claim 9, wherein the portion of the transistor gate stack that includes the halogens in one or more of the transistors of the first type includes the gate electrode material.

15. The IC structure according to claim 9, wherein:
the transistor gate stack of the individual transistor further includes an insulator material between the high-k dielectric and the channel material,
a dielectric constant of the insulator material is lower than a dielectric constant of the high-k dielectric, and
the portion of the transistor gate stack that includes the halogens in one or more of the transistors of the first type includes the insulator material.

16. The IC structure according to claim 9, wherein a concentration of the halogens increases further away from the channel material.

17. The IC structure according to claim 9, wherein an average concentration of the halogens in the at least a portion of the transistor gate stack in the one or more of the transistors of the first type is at least about 10¹⁵ atoms per cubic centimeter.

18. The IC structure according to claim 9, further comprising a dipole material between the high-k dielectric and the channel material in the one or more of the transistors of the first type, wherein the dipole material is absent between the high-k dielectric and the channel material in all of the transistors of the second type.

19. An integrated circuit (IC) structure, comprising:
a memory cell, comprising:
a first inverter comprising a transistor M1 and a transistor M2, and
a second inverter comprising a transistor M3 and a transistor M4, the second inverter coupled to the first inverter,
wherein:
the transistors M1 and M3 are transistors of a first type,
the transistors M2 and M4 are transistors of a second type,
one of the first type and the second type is an N-type and another one of the first type and the second type is a P-type,
a gate stack of at least one of the transistors M1 and M3 includes either a dipole material or halogens, and
none of the gate stacks of the transistors M2 and M4 include the dipole material or the halogens.

20. The IC structure according to claim 19, wherein the gate stack of each of the transistors M1 and M3 includes either the dipole material or the halogens.
